(19) United States
(12) Patent Application Publication
(10) Pub. No.: US 2020/0020707 A1
(43) Pub. Date: Jan. 16, 2020

(54) SEMICONDUCTOR PROCESSING METHOD FOR MANUFACTURING ANTIFUSE STRUCTURE WITH IMPROVED IMMUNITY AGAINST ERRONEOUS PROGRAMMING

(71) Applicant: eMemory Technology Inc., Hsin-Chu (TW)

(72) Inventors: Chao-Kan Yang, Hsinchu County (TW); Lun-Chun Chen, Hsinchu County (TW)

(21) Appl. No.: 16/427,313

(22) Filed: May 30, 2019

Related U.S. Application Data
(60) Provisional application No. 62/697,411, filed on Jul. 13, 2018.

(51) Int. Cl. H01L 27/112; G11C 17/16

(52) U.S. Cl. CPC H01L 27/11206; G11C 17/16

(57) ABSTRACT

A semiconductor processing method is used for manufacturing an antifuse structure. The semiconductor processing method may include using a first mask for exposing a first well region of a semiconductor substrate, performing a first Boron implantation operation to implant Boron into the first well region, using a second mask for exposing the first well region and the second well region of the semiconductor substrate, and performing a second Boron implantation operation to implant Boron into the first well region and the second well region.

### CROSS REFERENCE TO RELATED APPLICATIONS

This application claims priority to provisional Patent Application No. 62/697,411, filed Jul. 13, 2018, and incorporated herein by reference in its entirety.

### BACKGROUND OF THE INVENTION

### 1. Field of the Invention

The invention is related to a semiconductor processing method, and more particularly, a semiconductor processing method used for manufacturing an antifuse structure with improved immunity against erroneous programming.

### 2. Description of the Prior Art

In the field of memory cell manufacture, an antifuse structure maybe used, and the antifuse structure maybe formed on a well region. For example, when an antifuse structure includes a thin oxide n-type metal-oxide-semiconductor (NMOS), two highly doped n-type (often denoted as N⁺) regions may be formed at two sides of an antifuse layer on a p-type well.

When a high voltage is applied to the antifuse layer, the antifuse layer may be unwantedly broken through by the high voltage. This may lead to an excessive leak current, and the memory cell may be erroneously programmed.

In order to avoid erroneously programming a memory cell, a solution is required to improve the immunity of an antifuse structure against an erroneous programming operation caused by disturbance of a high voltage. Moreover, a solution using additional mask(s) is not preferred for cost considerations.

### SUMMARY OF THE INVENTION

An embodiment provides a semiconductor processing method for manufacturing an antifuse structure. The semiconductor processing method may include using a first mask for exposing a first well region of a semiconductor substrate; performing a first Boron implantation operation to implant Boron into the first well region; using a second mask for exposing the first well region and the second well region of the semiconductor substrate; and performing a second Boron implantation operation to implant Boron into the first well region and the second well region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a sectional view of a memory cell according to an embodiment.

FIG. 2 illustrates a flowchart of a method according to an embodiment.

FIG. 3 and FIG. 4 illustrate a process of performing the method of FIG. 2 according an embodiment.

FIG. 5 illustrates a flowchart of a method according to an embodiment.

FIG. 6 to FIG. 8 illustrate a process of performing the method of FIG. 5 according an embodiment.

FIG. 9 illustrates an n-type metal-oxide-semiconductor formed on the first well region according to an embodiment.

FIG. 10 illustrates a flowchart of a method used to generated the n-type metal-oxide-semiconductor of FIG. 9 according to an embodiment.

FIG. 11 to FIG. 14 illustrate top views of four types of memory cells according to embodiments.

### DETAILED DESCRIPTION

According to an embodiment, it maybe preferred for an antifuse structure to have a higher threshold voltage (often denoted as Vt). When an antifuse structure has a higher threshold voltage, it is more difficult for a high voltage to break through an antifuse layer to cause an erroneous programming operation. Hence, a solution without increasing the number of masks may be required to adjust a threshold voltage of an antifuse structure.

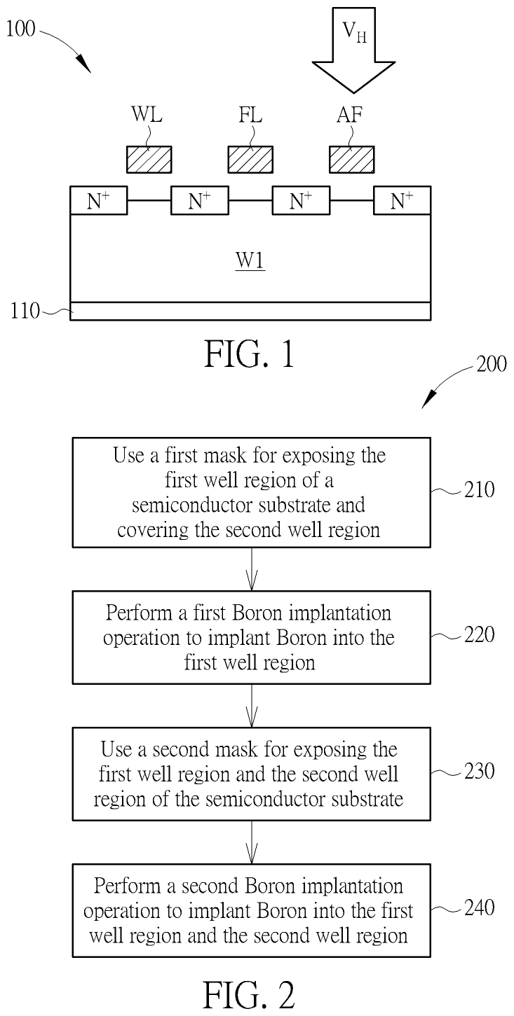

FIG. 1 illustrates a sectional view of a memory cell 100 according to an embodiment. As shown in FIG. 1, the memory cell 100 may be formed on a first well region W1, and the memory cell 100 may include a word line layer WL, a following line layer FL, an antifuse layer AF, and a plurality of doped regions N³⁰ . The first well region W1 may be formed as a low voltage p-type well (a.k.a. LVPW), and the first well region W1 maybe implanted with Boron using an LVPW setting according to an embodiment. However, when the first well region W1 is a low voltage p-type well, the threshold voltage Vt of the memory cell 100 may be so low that the antifuse layer AF may be more easily broken through by a high voltage V_{H}, and the memory cell 100 may be erroneously programed. Hence, the first well region W1 maybe adjusted to heighten the threshold voltage Vt of the memory cell 100. In the condition of FIG. 1, the Boron concentration of the first well region W1 may be concentration C1, and the concentration C1 may be expressed as an equation (eq-1).

C1=C_{LVPW} (eq-1).

C_{LVPW} may be Boron concentration corresponding to the low voltage p-type well (LVPW) setting.

According to an embodiment, a method for increasing the threshold voltage Vt of the memory cell 100 may include implanting Boron ions into the first well region W1. However, in order to increase the Boron concentration of the first well region W1, a plurality of Boron implantation operations may be performed, and each of the Boron implantation operations may require a dedicated mask for exposing regions needing Boron implantation and covering other regions. Hence, it is difficult to reduce the number of masks.

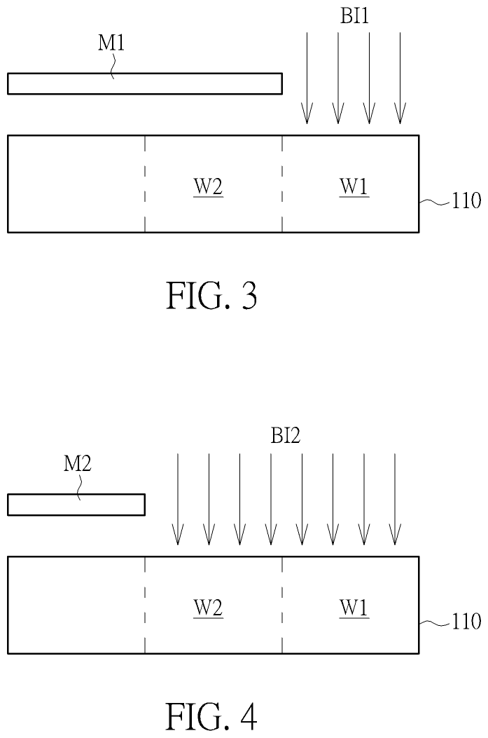

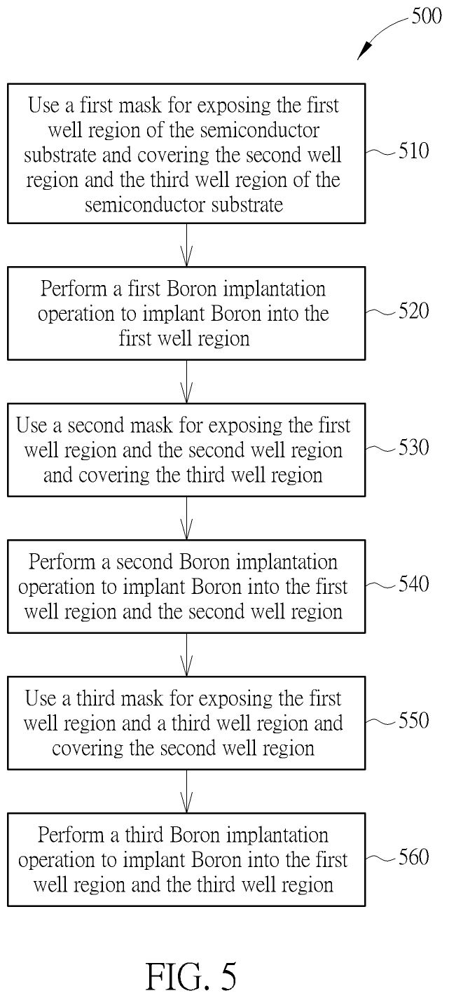

FIG. 2 illustrates a flowchart of a method 200 according to an embodiment. FIG. 3 and FIG. 4 illustrate a process of performing the method 200 of FIG. 2 according to an embodiment. The method 200 may be used for adjusting the Boron concentration of the first well region W1 without using additional mask(s). The method 200 may include the following steps.

Step 210: use a first mask Ml for exposing the first well region W1 of a semiconductor substrate 110 and covering the second well region W2;

Step 220: perform a first Boron implantation operation BI1 to implant Boron into the first well region W1;

Step 230: use a second mask M2 for exposing the first well region W1 and the second well region W2 of the semiconductor substrate 110; and

Step 240: perform a second Boron implantation operation BI2 to implant Boron into the first well region W1 and the second well region W2.

FIG. 3 may be corresponding to Step 210 and Step 220 of FIG. 2, and FIG. 4 may be corresponding to Step 230 and Step 240 of FIG. 2. As shown in FIG. 2 to FIG. 4, the first Boron implantation operation BI1 may be used to increase the Boron concentration of the first well region W1. The second implantation operation BI2 may be used to further increase the Boron concentration of the first well region W1 and increase the Boron concentration of the second well region W2. As shown in FIG. 3 and FIG. 4, the first well region W1 may be implanted with Boron twice, so the Boron concentration of the first well region W1 may be increased, a memory cell (e.g., 100) formed on the first well region W1 may have a higher threshold voltage Vt, and the memory cell may have improved immunity against incorrect program operation caused by a high voltage (e.g., V_{H} in FIG. 1) breaking through an antifuse layer.

In the example of FIG. 3 to FIG. 4, merely two masks (i.e., M1 and M2) and two Boron implantation operations (e.g., BI1 and BI2) may be required for adjusting the Boron concentration of the first well region W1 twice and adjusting the Boron concentration of the second well region W2 once. However, according to prior art, when intending to implant Boron to the first well region W1 twice and the second well region W2 once, at least three masks and three Boron implantation operations are required. For example, according to prior art, a first dedicated mask may be used to expose the first well region W1 to perform a first Boron implantation operation to the first well region W1, a second dedicated mask may be used to expose the second well region W2 to perform a second Boron implantation operation to the second well region W2, and a third dedicated mask may be used to expose the first well region W1 to perform a third Boron implantation operation. Hence, as compared with prior art, fewer masks and Boron implantation operations may be required to adjust the Boron concentration of the first well region W1 and the second well region W2 according to an embodiment.

According to an embodiment, in FIG. 2 to FIG. 4, the first well region W1 may be a low voltage (a.k.a. LV) well region, and the second well region W2 may be a middle voltage (a.k.a. MV) well region. According to another embodiment, the first well region W1 may be a low voltage well region, and the second well region W2 may be a high voltage (a.k.a. HV) well region.

According to an embodiment, in FIG. 2 to FIG. 4, the first Boron implantation operation BI1 may be corresponding to a low voltage p-type well (LVPW) setting, and the second Boron implantation operation BI2 may be corresponding to a high voltage p-type well (a.k.a. HVPW) setting. In this condition, the Boron concentration of the first well region W1 may be adjusted to concentration C2, where C2 may be expressed as an equation (eq-2).

C2=f₂(C_{LVPW}, C_{HVPW}) (eq-2).

In the equation (eq-2), f₂( ) may be a function, C_{LVPW} may be as described above, and C_{HVPW} may be Boron concentration corresponding to the high voltage p-type well (HVPW) setting, where the concentration C2 may be positively correlated with the concentration C_{LVPW} and C_{HVPW}. For example, C2 may be (but not limited to) a sum of C_{LVPW} and C_{HVPW}, that is C2=C_{LVPW}+C_{HVPW}. In this condition, because the first well region W1 may be implanted with Boron twice, once with the LVPW setting and once with the HVPW setting, the concentration C2 may be higher than the concentration C1.

According to another embodiment, the first Boron implantation operation BI1 may be corresponding to a low voltage p-type well (LVPW) setting, and the second Boron implantation operation BI2 may be corresponding to a high voltage p-type lightly doped drain (a.k.a. HVPLDD) setting. In this condition, the Boron concentration of the first well region W1 may be adjusted to concentration C3, where C3 may be expressed as an equation (eq-3).

C3=f₃(C_{LVPW}, C_{HVPLDD}) (eq-3).

In the equation (eq-2), f₃( ) may be a function, C_{HPVLDD} may be Boron concentration corresponding to the high voltage p-type lightly doped drain (HVPLDD) setting, where the concentration C3 may be positively correlated with the concentration C_{LVPW} and C_{HVPLDD}. For example, C3 may be (but not limited to) a sum of C_{LVPW} and C_{HVPLDD}, that is C3=C_{LVPW}+C_{HVPLDD}. In this condition, because the first well region W1 may be implanted with Boron twice, once with the LVPW setting and once with the HVPLDD setting, the concentration C3 may be higher than the concentration C1.

According to yet another embodiment, the first Boron implantation operation BI1 may be corresponding to a low voltage p-type well (LVPW) setting, and the second Boron implantation operation BI2 may be corresponding to a medium voltage p-type well (a.k.a. MVPW) setting. In this condition, the Boron concentration of the first well region W1 may be adjusted to concentration C4, where C4 may be expressed as an equation (eq-4).

C4=f₄(C_{LVPW}, C_{MVPW)} (eq-4).

In the equation (eq-2), f₄( ) may be a function, and C_{MVPW} may be Boron concentration corresponding to the medium voltage p-type well (MVPW) setting, where the concentration C4 may be positively correlated with the concentration C_{LVPW} and C_{MVPW}. For example, C4 may be (but not limited to) a sum of C_{LVPW} and C_{MVPW}, that is C4=C_{LVPW}+C_{MVPW}. In this condition, because the first well region W1 may be implanted with Boron twice, once with the LVPW setting and once with the MVPW setting, the concentration C4 may be higher than the concentration C1.

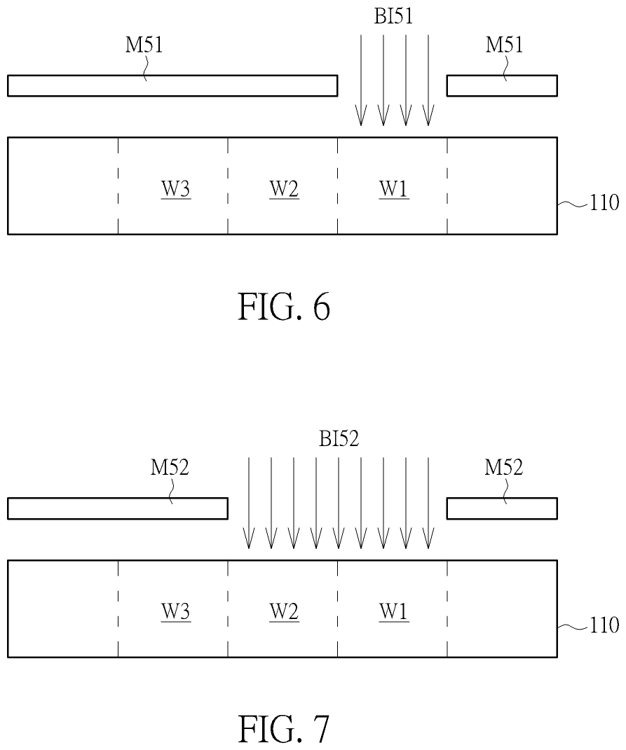

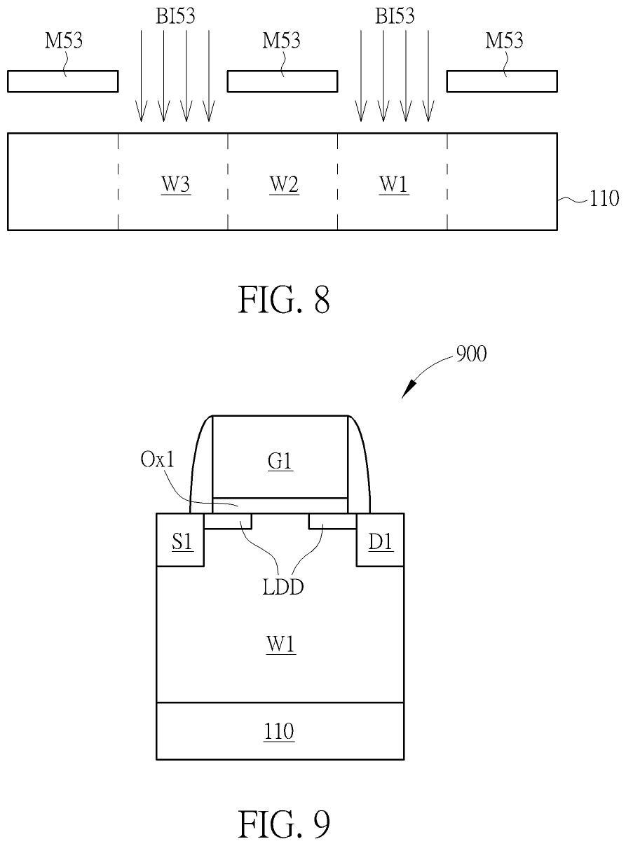

FIG. 5 illustrates a flowchart of a method 500 according to an embodiment. FIG. 6 to FIG. 8 illustrate a process of performing the method 500 of FIG. 5 according an embodiment. The method 500 may be used for adjusting the Boron concentration of the first well region W1 without using additional mask(s). The method 500 may include the following steps.

Step 510: use a first mask M51 for exposing the first well region W1 of the semiconductor substrate 110 and covering the second well region W2 and the third well region W3 of the semiconductor substrate 110;

Step 520: perform a first Boron implantation operation BI51 to implant Boron into the first well region W1;

Step 530: use a second mask M52 for exposing the first well region W1 and the second well region W2 and covering the third well region W3;

Step 540: perform a second Boron implantation operation BI52 to implant Boron into the first well region W1 and the second well region W2;

Step 550: use a third mask M53 for exposing the first well region W1 and a third well region W3 and covering the second well region W2; and

Step 560: perform a third Boron implantation operation BI53 to implant Boron into the first well region W1 and the third well region W3.

FIG. 6 may be corresponding to Step 510 and Step 520 of FIG. 5, FIG. 7 may be corresponding to Step 530 and Step 540 of FIG. 5, and FIG. 8 may be corresponding to Step 550 and Step 560 of FIG. 5. As shown in FIG. 5 to FIG. 8, the first Boron implantation operation BI51 may be used to increase the Boron concentration of the first well region W1. The second implantation operation BI52 may be used to further increase the Boron concentration of the first well region W1 and increase the Boron concentration of the second well region W2. The third implantation operation BI53 may be used to yet further increase the Boron concentration of the first well region W1 and increase the Boron concentration of the third well region W3. As shown in FIG. 6 to FIG. 8, the first well region W1 may be implanted with Boron three times, so the Boron concentration of the first well region W1 may be increased, a memory cell (e.g., 100) formed on the first well region W1 may have a higher threshold voltage Vt, and the memory cell may have improved immunity against incorrect program operation caused by a high voltage breaking through an antifuse layer.

In the example of FIG. 6 to FIG. 8, merely three masks (i.e., M51, M52 and M52) and three Boron implantation operations (e.g., BI51, BI52 and BI53) may be required for adjusting the Boron concentration of the first well region W1 three times and adjusting the Boron concentration of the second well region W2 and the third well region W3 once. However, according to prior art, when intending to implant Boron to the first well region W1 three times and implant Boron to the second well region W2 and the third well region W3 once, at least five masks and five Boron implantation operations are required. For example, according to prior art, a first dedicated mask may be used to expose the first well region W1 to perform a first Boron implantation operation to the first well region W1, a second dedicated mask may be used to expose the second well region W2 to perform a second Boron implantation operation to the second well region W2, a third dedicated mask may be used to expose the first well region W1 to perform a third Boron implantation operation, a fourth dedicated mask may be used to expose the third well region W3 to perform a fourth Boron implantation operation, and a fifth dedicated mask may be used to expose the first well region W1 to perform a fifth Boron implantation operation. Hence, as compared with prior art, fewer masks and Boron implantation operations maybe required to adjust the Boron concentration of the first well region W1, the second well region W2 and the third well region W3 according to an embodiment.

According to an embodiment, in FIG. 2 to FIG. 4, the first well region W1 maybe a low voltage (a.k.a. LV) well region, and the second well region W2 may be a middle voltage (a.k.a. MV) well region. According to another embodiment, the first well region W1 may be a low voltage well region, and the second well region W2 may be a high voltage (a.k.a. HV) well region.

According to an embodiment, in FIG. 6 to FIG. 8, the first well region W1 maybe a low voltage (LV) well region, the second well region W2 maybe a middle voltage (MV) well region, and the third well region W3 may be a high voltage (HV) well region.

According to an embodiment, the first Boron implantation operation BI51 maybe corresponding to a low voltage p-type well (LVPW) setting, the second Boron implantation operation BI52 may be corresponding to a medium voltage p-type well (MVPW) setting, and the third Boron implantation operation may be corresponding to a high voltage p-type well (HVPW) setting.

In this condition, the Boron concentration of the first well region W1 may be adjusted to concentration C5, where C5 may be expressed as an equation (eq-5).

C5=f₅(C_{LVPW}, C_{MVPW}, C_{HVPW}) (eq-5).

The concentration C_{LVPW}, C_{MVPW} and C_{LVPW} may be as describe above, where the concentration C5 may be positively correlated with the concentration C_{LVPW}, C_{MVPW} and C_{HVPW}. For example, C5 may be (but not limited to) a sum of C_{LVPW}, C_{MVPW} and C_{HVPW}, that is C5=C_{LVPW}+C_{MVPW}+C_{HVPW}. In this condition, because the first well region W1 may be implanted with Boron three times, once with the LVPW setting, once with the MVPW setting and once with the HVPW setting, the concentration C5 may be higher than the concentration C1.

Regarding FIG. 2 to FIG. 4 and FIG. 5 to FIG. 8, as described above, the Boron concentration of the first well region W1 may be adjusted to be one of the concentrations C1 to C5 by means of a set of mask(s) and a set of Boron implantation operation(s). According to embodiments, the relationship of foresaid concentrations C1 to C5 may be C1<C2<C3<C4<C5. The relationship among the threshold voltage Vt corresponding to the memory cell Vt and the abovementioned concentration C1 to C5 may be as shown in Table-1.

TABLE 1

| | | | Corresponding | Immunity |
|---|---|---|---|---|
| | The | Corresponding | set of mask | against |
| Condi- | threshold | concentration | and Boron | erroneous |
| tion | voltage Vt | of Boron | implantation | programming |
| 1 | Highest | C5 | LVPW, MVPW, | Highest |
| | | | HVPW | |
| 2 | Second | C4 | LVPW, MVPW | Second |
| | highest | | | highest |
| 3 | Third | C3 | LVPW, | Third |
| | highest | | HVPLDD | highest |
| 4 | Fourth | C2 | LVPW, HVPW | Fourth |
| | highest | | | highest |
| 5 | lowest | C1 | LVPW | lowest |

The condition 1 in Table-1 may be corresponding to FIG. 5 to FIG. 8. Each of the condition 2 to condition 4 in Table-1 may be corresponding to FIG. 2 to FIG. 4. The condition 5 maybe corresponding to FIG. 1 where the first well region W1 is an LVPW. As described in FIG. 2 to FIG. 8 and Table-1, by selecting the mask set used for performing Boron implantation operations, the immunity of a memory cell against erroneous programming may be improved without using additional masks in the manufacture process.

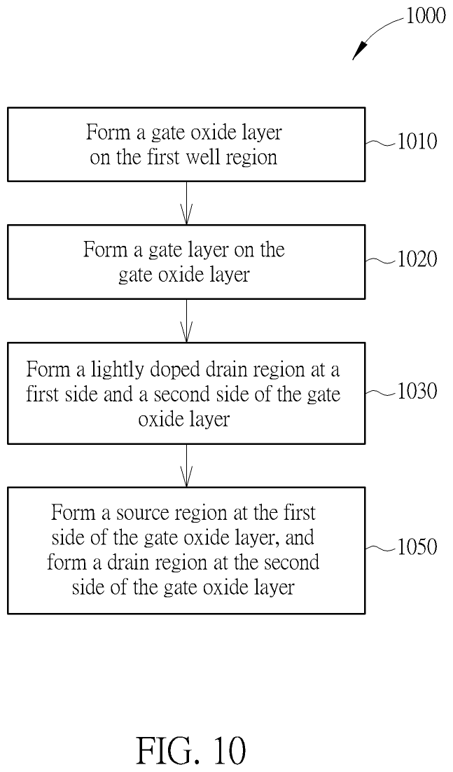

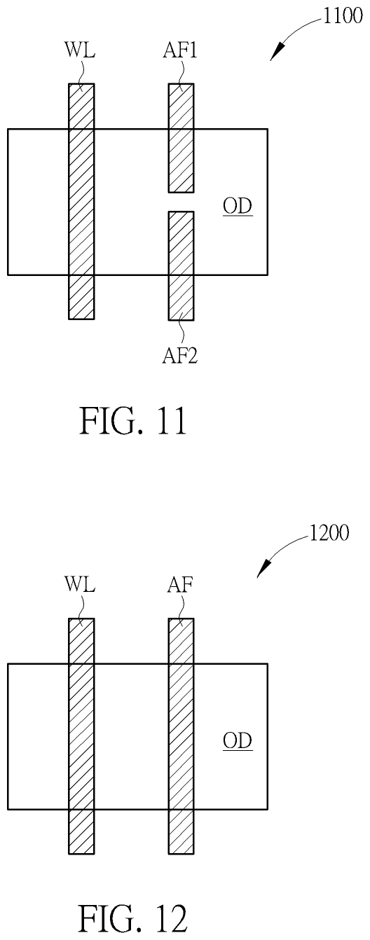

FIG. 9 illustrates an n-type metal-oxide-semiconductor (NMOS) 900 formed on the first well region W1 according to an embodiment. FIG. 10 illustrate a flowchart of a method 1000 used to generate the n-type metal-oxide-semiconductor 900 of FIG. 9 according to an embodiment. The method 1000 may include the following steps.

Step 1010: form a gate oxide layer Ox1 on the first well region W1;

Step 1020: form a gate layer G1 on the gate oxide layer Ox1;

Step 1030: form a lightly doped drain region LDD at a first side and a second side of the gate oxide layer Ox1; and

Step 1050: form a source region S1 at the first side of the gate oxide layer Ox1, and form a drain region D1 at the second side of the gate oxide layer Ox1.

The n-type metal-oxide-semiconductor 900 may be a portion of the memory cell 100 of FIG. 1 according to an embodiment. Because the n-type metal-oxide-semiconductor 900 may be formed on the first well region W1, and the threshold voltage of the first well region W1 may be increased by means of the method 200 and/or the method 500 described above, the immunity of the memory cell 100 against erroneous programming may be improved without using additional masks in the manufacturing process. According to an embodiment, the Step 1030 may be optionally performed since the lightly doped drain region LDD may be omitted in some applications.

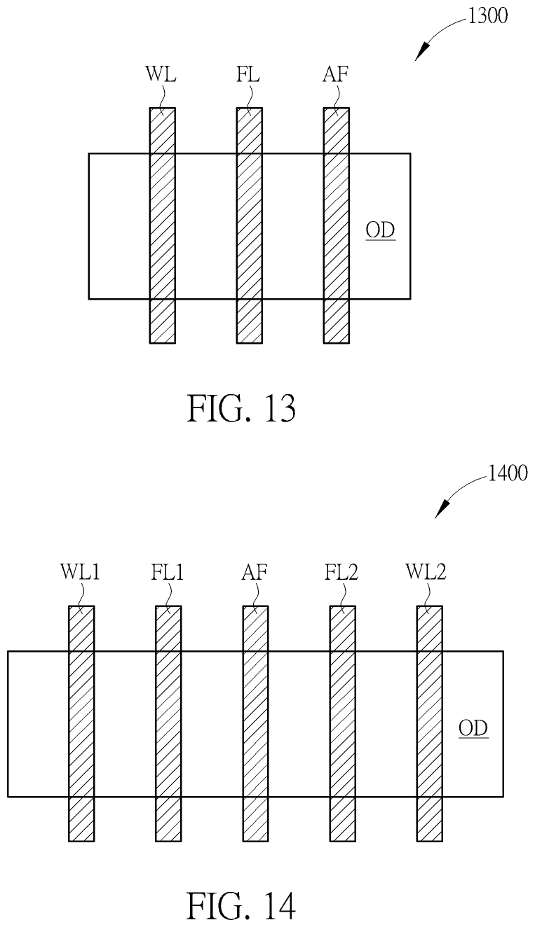

FIG. 11 to FIG. 14 illustrate top views of four types of memory cells according to embodiments. By means of the method 200 corresponding to FIG. 2 to FIG. 4 or the method 500 corresponding to FIG. 5 to FIG. 8, a generated memory cell may be one of the types shown in FIG. 11 to FIG. 14. In a memory cell 1100 of FIG. 11, a word line layer WL, an antifuse layer AF1 and another antifuse layer AF2 may be formed on an oxide diffusion layer OD, and the layout may be shown as FIG. 11. In a memory cell 1200 of FIG. 12, a word line layer WL and an antifuse layers AF may be formed on an oxide diffusion layer OD, and the layout may be shown as FIG. 12. In a memory cell 1300 of FIG. 13, a word line layer WL, a following line layer FL and an antifuse layer AF may be formed on an oxide diffusion layer OD, and the layout may be shown as FIG. 13. In a memory cell 1400 of FIG. 14, two word line layers WL1 and W12, an antifuse layers AF, and two following line layer FL1 and FL2 may be formed on an oxide diffusion layer OD, and the layout may be shown as FIG. 14. In FIG. 11 to FIG. 14, each of the word line layers (e.g., WL, WL1 and WL2), the antifuse layers (e.g. AF, AF1 and AF2) and the following line layers (e.g., FL, FL1 and FL2) may be generated using a polycrystalline material or a polysilicon material. FIG. 11 to FIG. 14 may be merely examples, the types of memory cell generated using a method of an embodiment is not limited to the types of memory cell shown in FIG. 11 to FIG. 14.

In summary, by means of a method provided by an embodiment, additional Boron implantation operation(s) may be performed to a well region without using additional mask(s), a threshold voltage of an antifuse structure formed on the well region may be increased, and a memory cell with the antifuse structure may have better immunity against erroneous programing caused by a high voltage breaking through a gate layer and a related unwanted leakage current.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor processing method for manufacturing an antifuse structure, comprising:
using a first mask for exposing a first well region of a semiconductor substrate;
performing a first Boron implantation operation to implant Boron into the first well region;
using a second mask for exposing the first well region and the second well region of the semiconductor substrate; and
performing a second Boron implantation operation to implant Boron into the first well region and the second well region.

2. The semiconductor processing method of claim 1, wherein the first well region is a low voltage well region, and the second well region is a middle voltage well region.

3. The semiconductor processing method of claim 1, wherein the first well region is a low voltage well region, and the second well region is a high voltage well region.

4. The semiconductor processing method of claim 1, wherein:
the first Boron implantation operation is corresponding to a low voltage p-type well setting; and
the second Boron implantation operation is corresponding to a high voltage p-type well setting.

5. The semiconductor processing method of claim 1, wherein:
the first Boron implantation operation is corresponding to a low voltage p-type well setting; and
the second Boron implantation operation is corresponding to a high voltage p-type lightly doped drain (LDD) setting.

6. The semiconductor processing method of claim 1, wherein:
the first Boron implantation operation is corresponding to a low voltage p-type well setting; and
the second Boron implantation operation is corresponding to an medium voltage p-type well setting.

7. The semiconductor processing method of claim 1, further comprising:
forming a gate oxide layer on the first well region;
forming a gate layer on the gate oxide layer; and
forming a source region at a first side of the gate oxide layer, and forming a drain region at a second side of the gate oxide layer.

8. The semiconductor processing method of claim 7, further comprising:
forming a lightly doped drain region at the first side and the second side of the gate oxide layer.

9. The semiconductor processing method of claim 1, further comprising:
using a third mask for exposing the first well region and a third well region of the semiconductor substrate; and
performing a third Boron implantation operation to implant Boron into the first well region and the third well region.

10. The semiconductor processing method of claim 9, wherein the first well region is a low voltage well region, the second well region is a middle voltage well region, and the third well region is a high voltage well region.

11. The semiconductor processing method of claim 9, wherein:
the first Boron implantation operation is corresponding to a low voltage p-type well setting;
the second Boron implantation operation is corresponding to a medium voltage p-type well setting; and
the third Boron implantation operation is corresponding to a high voltage p-type well setting.

12. The semiconductor processing method of claim 9, further comprising:
forming a gate oxide layer on the first well region;
forming a gate layer on the gate oxide layer; and
forming a source region at a first side of the gate oxide layer, and forming a drain region at a second side of the gate oxide layer.

13. The semiconductor processing method of claim 12, further comprising:
forming a lightly doped drain region at the first side and the second side of the gate oxide layer.
